(19) United States
(12) Patent Application Publication
(10) Pub. No.: US 2022/0278085 A1
(43) Pub. Date: Sep. 1, 2022

(54) METHOD FOR CONNECTING AN ELECTRICAL DEVICE TO A BOTTOM UNIT BY USING A SOLDERLESS JOINT

(71) Applicant: Infineon Technologies AG, Neubiberg (DE)

(72) Inventors: Chau Fatt CHIANG, Melaka (MY); Paul Armand Asentista CALO, Villach (AT); Chan Lam CHA, Melaka (MY); Kok Yau CHUA, Melaka (MY); Chee Hong LEE, Melaka (MY); Swee Kah LEE, Melaka (MY); Theng Chao LONG, Melaka (MY); Jayaganasan NARAYANASAMY, Melaka (MY); Khay Chwan Andrew SAW, Melaka (MY)

(73) Assignee: Infineon Technologies AG, Neubiberg (DE)

(21) Appl. No.: 17/677,055

(22) Filed: Feb. 22, 2022

(30) Foreign Application Priority Data
Feb. 26, 2021 (DE) 10 2021 104 696.3

(51) Int. Cl. H01L 25/16; H01L 23/13; H01L 21/48; H01L 25/00; H01L 25/10; H01L 23/498

(52) U.S. Cl. CPC H01L 25/16; H01L 23/13; H01L 21/4846; H01L 25/50; H01L 25/105; H01L 23/498; H01L 2225/1041; H01L 2225/1047

(57) ABSTRACT

The method for fabricating an electrical module is disclosed. In one example, the method includes providing a bottom unit comprising a plateable encapsulant. Selective areas of the bottom unit are activated thereby turning them into electrically conductive regions. At least one electrical device comprising external contact elements is provided. The method includes placing the electrical device on the bottom unit so that the external contact elements are positioned above at least a first subset of the electrically conductive regions, and performing a plating process on the electrically conductive regions for generating plated regions and for electrically connecting the external contact elements with at least a first subset of the plated regions.

### CROSS-REFERENCE TO RELATED APPLICATION

This Utility patent application claims priority to German Patent Application No. 10 2021 104 696.3, filed Feb. 26, 2021, which is incorporated herein by reference.

### TECHNICAL FIELD

The present disclosure is related to a method for fabricating an electrical module and to an electrical module.

### BACKGROUND

For fabricating electrical or electronic modules it sometimes becomes desirable to connect a first device package to a second one or, more generally, to a bottom unit which also comprises an encapsulant. Such package-to-package assemblies may enhance the performance of the module without any development effort towards monolithic solutions.

Currently the manufacturers install an additional device package or passive component on top of a base package by leads-on-leads welding, or by connecting a solder ball of the top package by soldering to the bottom package, or joining between passive terminals to exposed metals which connect to both packages. Mostly such package-to-package interconnections are achieved with solder joints. However, these soldering methods result in higher space requirement between the packages, higher amount of solder requirement to stabilize the joining the joining process, a higher manufacturing complexity, and an inflexibility of the joining pad position.

For these and other reasons there is a need for the presence disclosure.

### SUMMARY

A first aspect of the present disclosure is related to a method for fabricating an electrical module, the method comprising providing a bottom unit comprising a plateable encapsulant, activating selective areas of the bottom unit and thereby turning them into electrically conductive regions, providing at least one electrical device comprising external contact elements, placing the electrical device on the bottom unit so that the external contact elements are positioned above at least a first subset of the electrically conductive regions, and performing a plating process on the electrically conductive regions for generating plated regions and for electrically connecting the external contact elements with at least a first subset of the plated regions.

A second aspect of the present disclosure is related to an electrical module comprising a bottom unit comprising a plateable encapsulant wherein selective areas are activated and turned into electrically conductive regions, at least one electrical device comprising external contact elements and being disposed on the bottom unit with the external contact elements being electrically connected with a first subset of the electrically conductive regions by means of a first subset of plated regions.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows a flow diagram of a method for fabricating an electrical module according to an example.

FIG. 2 comprises FIG. 2A to 2C and shows schematic side view representations of intermediate products and an electrical module for illustrating a method for fabricating an electrical module according to an example in which a semiconductor package is mounted onto a bottom unit.

FIG. 3 comprises FIG. 3A to 3E and shows schematic representations of intermediate products and an electrical module for illustrating a method for fabricating an electrical module according to an example in which two semiconductor packages and two passive components are mounted onto a bottom unit by using a jig to press the devices onto the bottom unit.

FIG. 4 comprises FIG. 4A to 4E and shows schematic top view representations of intermediate products and an electrical module for illustrating a method for fabricating an electrical module according to an example in which two semiconductor packages and two passive components are mounted onto a bottom unit by using a high thermal glue to adhere the devices to the bottom unit.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, “leading”, “trailing”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

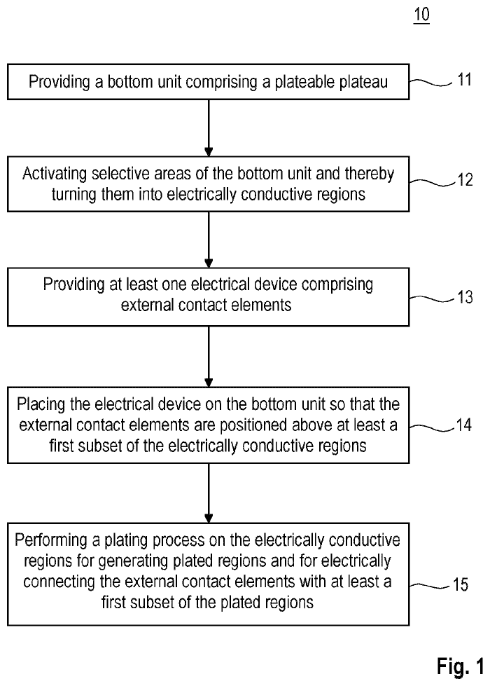

FIG. 1 shows a flow diagram of a method for fabricating an electrical module according to an example.

The method 10 according to FIG. 1 comprises providing a bottom unit comprising a plateable encapsulant (11), activating selective areas of the bottom unit and thereby turning them into electrically conductive regions (12), providing at least one electrical device comprising external contact elements (13), placing the electrical device on the bottom unit so that the external contact elements are positioned above at least a first subset of the electrically conductive regions at least a first subset of the electrically conductive regions (14), and performing a plating process on the electrically conductive regions for generating plated regions and for electrically connecting the external contact elements with at least a first subset of the plated regions (15). The term “above” in (14) can in particular mean that the external contact elements are not contacted with the electrically conductive regions.

The present disclosure offers significant advantages over the prior art techniques. In particular, it enables the fabrication of a flexible solderless package-to-package connection by use of placeable encapsulant and plating. The plating can be performed solely by electroless plating which means that no electrical energy consumption is needed so that the present disclosure offers a green solution. Moreover, as will be shown later in more detail, the fabrication can be carried out in a batched form which further contributes to the energy-saving green solution.

As mentioned above, the encapsulant comprises a laser-activatable material as, for example, an additive like a laser direct structuring (LDS) additive, embedded in an encapsulant host material, and sweeping the laser beam over the selected regions results in activating the laser-activatable material. According to an example thereof, the additive is selected from the group consisting of any kinds of metal insulated with powder (in nano size), copper chromium oxide (spinel), copper hydroxide phosphate, copper phosphate, copper chromium oxide spinel, a copper sulfate, a cuprous thiocyanate, an organic metal complex, a palladium/palladium-containing heavy metal complex, a metal oxide, a metal oxide-coated filler, antimony doped tin oxide coated on mica, a copper containing metal oxide, a zinc containing metal oxide, a tin containing metal oxide, a magnesium containing metal oxide, an aluminum containing metal oxide, a gold containing metal oxide, a silver containing metal oxide, and a combination thereof.

According to an embodiment of the method 10 of FIG. 1, the plating is carried out in a hybrid form, namely by applied both electroless plating and electrochemical plating. For example, the plating process may comprise a first process of electroless plating and a subsequent second process of electrochemical plating. This could turn out advantageous as usually the deposition rates of electrochemical plating are much higher as those of electroless plating.

According to an embodiment of the method 10 of FIG. 1, activating the selective areas is performed by a laser beam which can be either a continuous laser beam or a pulsed laser beam.

After placing the semiconductor package on the bottom unit, the semiconductor package is lying only loosely on the bottom substrate, but not yet securely fixed to the bottom unit is pressed against the bottom unit. Therefore it may be possible to press the semiconductor package against the bottom unit, in particular by means of a jig. A specific example thereof will be shown in more detail later.

As an alternative or in addition to pressing the semiconductor package against the bottom unit, it may also be possible to adhere the package body to the bottom unit after placing. According to a further example thereof the package body can be adhered to the bottom unit by means of a glue, in particular a thermally conductive glue. A specific example thereof will be shown in more detail later.

The present disclosure does not only allow the mounting of electrical devices like a semiconductor package or a passive component onto a bottom unit, but also the fabrication of electrical connection lines. Accordingly performing the plating process may comprise generating a second subset of plated regions by performing a plating process on a second subset of electrically conductive regions, wherein the second subset of plated regions comprises electrical connection lines. The electrical connection lines can be fabricated so as to connect different electrical or electronic devices with each other. A specific example thereof will be shown in more detail later.

The at least one electrical device can be a semiconductor package or a passive component. Moreover, the at least one electrical device may comprise at least one semiconductor package and at least one passive component. The devices can also be electrically connected with each other by electrical lines which can be fabricated as was described above.

The bottom unit may itself comprise a package like a semiconductor package comprising one or more electrical or electronic devices like semiconductor dies or passive components.

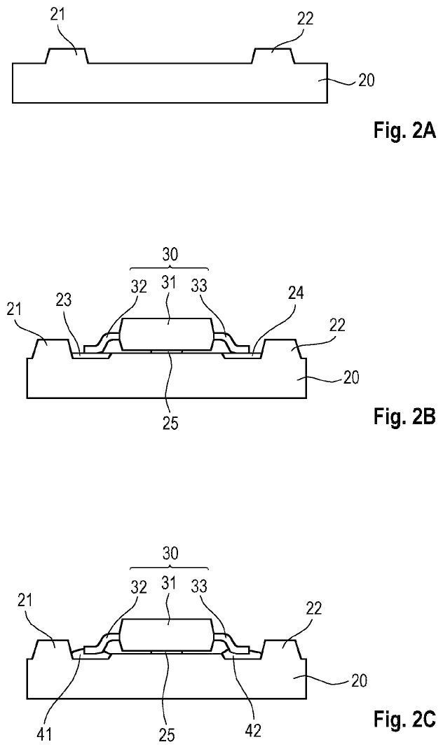

FIG. 2 comprises FIG. 2A to 2C and shows schematic side view representations of intermediate products and an electrical module for illustrating a method for fabricating an electrical module according to an example in which a semiconductor package is mounted onto a bottom unit.

FIG. 2A shows a cross-sectional side view on a bottom unit 20 which comprises a plateable encapsulant, in particular a plateable mold compound. The bottom unit 20 may comprise two protrusions 21 and 22 being located so that a distance between them is slightly larger than a length of a semiconductor package 30 to be mounted between the protrusions 21 and 22. In this way the protrusions 21 and 22 may have a function of a guide for mounting the semiconductor package 30. The protrusions 21 and 22 may have a trapezoidal or rectangular cross-section. The bottom unit 20 with the protrusions 21 and 22 can be fabricated, for example, by film-assisted molding (FAM). It should, however, be noted that the protrusions 21 and 22 are only optional and can also being omitted.

FIG. 2B shows a schematic cross-sectional side view on an intermediate product obtained after laser activating selected regions on the upper main surface of the bottom unit 20 and placing the semiconductor package 30 onto the bottom unit 20. The selectively laser activated regions 23 and 24 are located besides the protrusions 21 and 22, namely directly besides opposing side faces of the protrusions 21 and 22. By the laser activation these regions are turned into electrically conductive regions 23 and 24. The semiconductor package 30 comprises a package body 31 and two electrical leads 32 and 33 being connected with one or more electrical or electronic devices like semiconductor dies inside the package body 31, extending outwards and then bent downwards. The lower ends of the electrical leads 32 and 33 are to be positioned each one above one of the electrically conductive regions 23 and 24. They can be contacted with the electrically conductive regions 23 and 24 or they can be positioned above the electrically conductive regions 23 and 24 without contacting them so that there is a gap between the electrical leads 32 and 33 and the electrically conductive regions 23 and 24. More precisely, in case of an initial electroless plating it is necessary to have at least a partial gap between the electrical leads 32 and 33 and the electrically conductive regions 23 and 24. In one embodiment, optionally in order to make sure there is at least a partial gap between the electrical leads 32 and 33 and the electrically conductive regions 23 and 24 a protrusion 25 of a sufficient height can be provided on the top surface of the bottom device. Optionally the protrusion 25 can be formed during the molding process of the bottom device. In case of an initial electrochemical plating between the electrical leads 32 and 33 and the electrically conductive regions 23 and 24 should have direct contact, respectively.

It should be mentioned that in the embodiment as shown in FIG. 2 the electrical contact elements according to the present disclosure are given by electrical leads 32 and 33 such as those shown in FIGS. 2B and 2C. However, it can also be the case that the electrical contact elements according to the present disclosure are given by flat external electrical contact areas such as those used in leadless packages fabricated for surface mount technology (SMT).

It is to be noted that after placing the semiconductor package 30 onto the bottom unit 20 the leads 32 and 33 are not yet firmly connected with the electrically conductive regions 23 and 24 but only loosely lying on them. In order to prevent the semiconductor package 30 from sliding away in one of the subsequent handling steps, before placing the semiconductor package 30 onto the bottom unit 20 a protrusion 25 in the form of an adhesive layer 25 can be applied to the upper main surface of the package body 21 so that the semiconductor package 30 will be adhered to the bottom unit 20.

FIG. 2C shows a schematic cross-sectional side view on an electrical module obtained after performing electroless plating metal layers 41 and 42 onto the electrically conductive regions 23 and 24 and the lower ends of the leads 32 and 33 in order in order to firmly connect the leads 32 and 33 mechanically and electrically to the electrically conductive regions 23 and 24. It should be mentioned that it is also possible to conduct a first phase of electroless plating followed by a second phase of electrochemical plating as electrochemical plating is known to provide higher deposition rates than electroless plating.

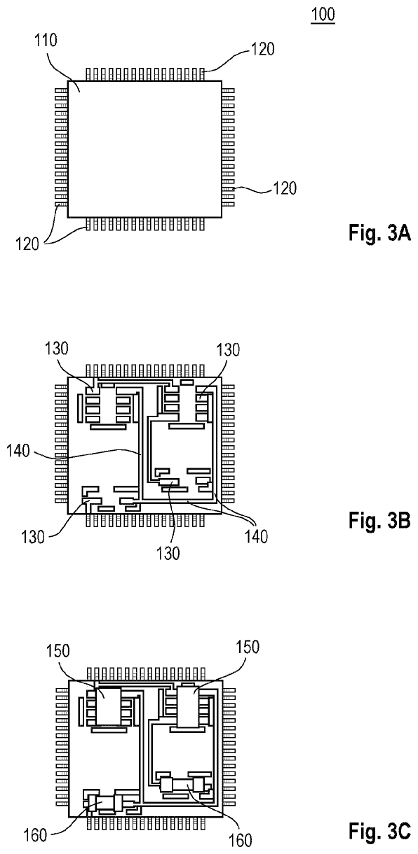

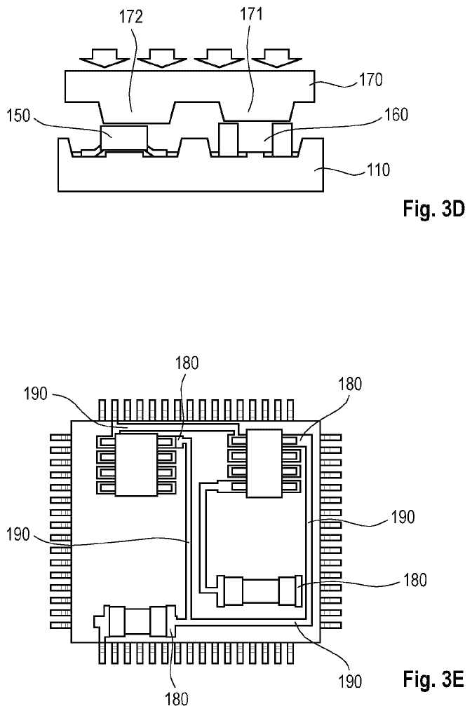

FIG. 3 comprises FIG. 3A to 3E and shows schematic top view representations of intermediate products and an electrical module for illustrating a method for fabricating an electrical module according to an example in which two semiconductor packages and two passive components are mounted onto a bottom unit by using a jig to press the devices onto the bottom unit.

FIG. 3A shows a top view on a bottom unit 100 which may be a semiconductor package. The bottom unit 100 further comprises a package body 110 which comprises a plateable encapsulant. The semiconductor package may further comprise within its package body 110 one or more electrical or electronic devices like semiconductor dies or passive components (not shown). The bottom unit 100 further comprises a plurality of external leads 120 which may either be already connected with the devices of the semiconductor package or to be connected later with electrical lines to be formed on the upper main surface of the package body 110.

FIG. 3B shows a top view on an intermediate product after activating selective areas of the bottom unit and thereby turning them into electrically conductive regions. The electrically conductive regions comprise a first subset 130 and a second subset 140 of electrically conductive regions. The first subset 130 comprises electrically conductive regions on which electrical or electronic devices are to be mounted later, and the second subset 140 comprises electrically conductive regions which are electrical connection lines between the devices or between one or more of the devices and external pins.

FIG. 3C shows a top view on an intermediate product after placing electrical or electronic devices on the first subset 130 of electrically conductive regions in a similar way as it was shown in FIG. 2. In the present embodiment two semiconductor packages 150 and two passive components 160 are mounted onto the electrically conductive regions. In difference to FIG. 2 no adhesive is applied to the surface of the package body 110 before placing the devices.

FIG. 3D shows a cross-sectional view of a portion of an intermediate product after placing the semiconductor packages 150 and passive components 160. It has been mentioned above that at this stage the semiconductor packages 150 and passive components 160 are not yet fixed to the bottom unit so that their placement must be secured in some way. In this embodiment this is not done by an adhesive but by pressing down the devices by mechanical means. More specifically a jig 170 can be used to press down the semiconductor packages 150 and passive components 160. The jig 170 may comprise protrusions 171 which may be aligned with the devices so that each one of the protrusions 171 which may be located above one of the devices 150 and 160. Pressing down the devices 150 and 160 has the effect that the hard material of the leads somewhat digs into the softer material of the bottom unit 110, i.e. the activated regions of the bottom unit 110.

FIG. 3E shows a top view on the fabricated electrical module after performing the plating process which can be performed as was described above in connection with FIG. 2C. Performing the plating process comprises generating a first subset of plated regions 180 and a second subset 190 of plated regions. The first subset of plated regions 180 comprises the joint regions between the leads of the devices and the first subset 130 of electrically conductive regions, and the second subset of plated regions 190 comprises the traces or electrical connection lines formed on the second subset of electrically conductive regions 140.

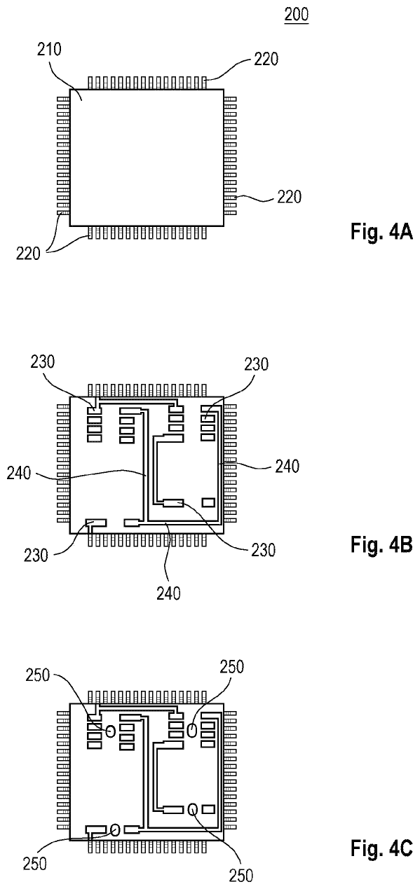

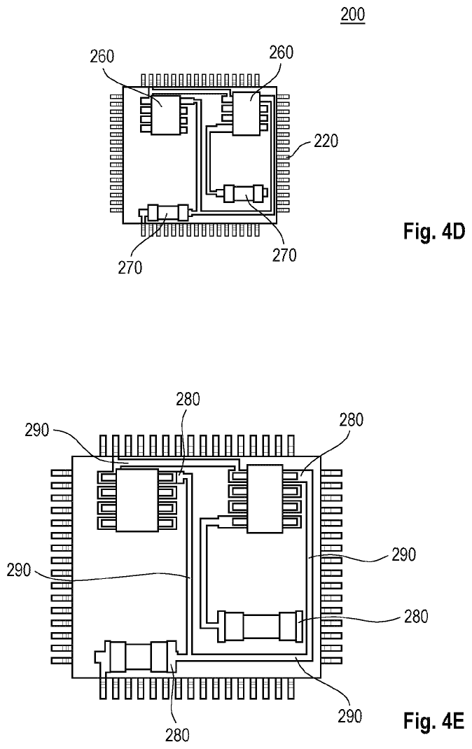

FIG. 4 comprises FIG. 4A to 4E and shows schematic top view representations of intermediate products and an electrical module for illustrating a method for fabricating an electrical module according to an example in which two semiconductor packages and two passive components are mounted onto a bottom unit by using a high thermal glue to adhere the devices to the bottom unit.

FIG. 4A shows a top view on a bottom unit 200 which may be a semiconductor package. The bottom unit 200 further comprises a package body 210 which comprises a plateable encapsulant. The semiconductor package may further comprise within its package body 210 one or more electrical or electronic devices like semiconductor dies or passive components (not shown). The bottom unit 200 further comprises a plurality of external leads 220 which may either be already connected with the devices of the semiconductor package or to be connected later with electrical lines to be formed on the upper main surface of the package body 210.

FIG. 4B shows a top view on an intermediate product after activating selective areas of the bottom unit and thereby turning them into electrically conductive regions. The electrically conductive regions comprise a first subset 230 and a second subset 240 of electrically conductive regions. The first subset 230 comprises electrically conductive regions on which electrical or electronic devices are to be mounted later, and the second subset 240 comprises electrically conductive regions which are electrical connection lines between the devices or between one or more of the devices and external pins.

FIG. 4C shows a top view on an intermediate product after applying an adhesive 250 to those portions of the surface of the package body 210 on which portions devices are to be placed later.

FIG. 4D shows a top view on an intermediate product after placing electrical or electronic devices on the first subset 230 of electrically conductive regions in a same way as it was shown in FIG. 2. In the present embodiment two semiconductor packages 260 and two passive components 270 are mounted onto the electrically conductive regions. Due to the adhesive 250 the devices 260 and 270 are securely fastened to the bottom unit 200 whereas the leads are loosely resting on the electrically conductive regions.

FIG. 4E shows a top view on the fabricated electrical module after performing the plating process which can be performed as was described above in connection with FIG. 2C. Performing the plating process comprises generating a first subset of plated regions 280 and a second subset 290 of plated regions. The first subset of plated regions 280 comprises the joint regions between the leads of the devices and the first subset 230 of electrically conductive regions, and the second subset of plated regions 290 comprises the traces or electrical connection lines formed on the second subset of electrically conductive regions 240.

### EXAMPLES

In the following, a method for fabricating an electrical module and an electrical module will be explained by means of examples.

Example 1 is a method for fabricating an electrical module, the method comprising providing a bottom unit comprising a plateable encapsulant, activating selective areas of the bottom unit and thereby turning them into electrically conductive regions, providing at least one electrical device comprising external contact elements, placing the electrical device on the bottom unit so that the external contact elements are positioned above at least a first subset of the electrically conductive regions, and performing a plating process on the electrically conductive regions for generating plated regions and for electrically connecting the external contact elements with at least a first subset of the plated regions.

Example 2 is the method according to Example 1, wherein the plating process comprises one or both of electroless plating and electrochemical plating.

Example 3 is the method according to Example 1 or 2, wherein the plating process comprises only electroless plating.

Example 4 is the method according to Example 3, wherein before placing the electrical device on the bottom unit a protrusion is disposed onto the bottom unit for supporting the electrical device.

Example 5 is the method according to Example 1 or 2, wherein the plating process comprises a first process of electroless plating and a subsequent second process of electrochemical plating.

Example 6 is the method according to any one of the preceding Examples, wherein activating selective areas is performed by a laser beam.

Example 7 is the method according to any one of the preceding Examples, wherein after placing the semiconductor package on the bottom unit, the semiconductor package is pressed against the bottom unit.

Example 8 is the method according to Example 7, wherein the semiconductor package is pressed against the bottom unit by means of a jig.

Example 9 is the method according to any one of the preceding Examples, wherein the semiconductor package comprises a package body, and by placing the semiconductor package on the bottom unit, the package body is adhered to the bottom unit.

Example 10 is the method according to Example 9, wherein the package body is adhered to the bottom unit by means of a glue.

Example 11 is the method according to Example 10, wherein the glue is thermally conductive.

Example 12 is the method according to any one of the preceding Examples, wherein performing the plating process comprises generating a second subset of plated regions by performing a plating process on a second subset of electrically conductive regions, wherein the second subset of plated regions comprises electrical connection lines.

Example 13 is the method according to any one of the preceding Examples, wherein the at least one electrical device is a semiconductor package or a passive component.

Example 14 is the method according to Example 13, wherein the at least one electrical device comprises at least one semiconductor package and at least one passive component.

Example 15 is the method according to any one of the preceding Examples, wherein the bottom unit comprises a semiconductor package.

Example 16 is an electrical module, comprising a bottom unit comprising a plateable encapsulant wherein selective areas are activated and turned into electrically conductive regions, at least one electrical device comprising external contact elements and being disposed on the bottom unit with the external contact elements being electrically connected with a first subset of the electrically conductive regions by means of a first subset of plated regions.

Example 17 is the electrical module according to Example 15, further comprising a second subset of electrically conductive regions being covered with a second subset of plated regions, wherein the second subset of plated regions comprises electrical connection lines.

Example 18 is the electrical module according to Example 16 or 17, wherein the at least one electrical device is a semiconductor package or a passive component.

Example 19 is the method according to any one Examples 16 to 18, wherein the at least one electrical device comprises at least one semiconductor package and at least one passive component.

Example 20 is the method according to any one of Examples 16 to 19, wherein the bottom unit comprises a semiconductor package.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A method for fabricating an electrical module, the method comprising
providing a bottom unit comprising a plateable encapsulant;
activating selective areas of the bottom unit and thereby turning them into electrically conductive regions;
providing at least one electrical device comprising external contact elements;
placing the electrical device on the bottom unit so that the external contact elements are positioned above at least a first subset of the electrically conductive regions; and
performing a plating process on the electrically conductive regions for generating plated regions and for electrically connecting the external contact elements with at least a first subset of the plated regions.

2. The method according to claim 1, wherein
the plating process comprises one or both of electroless plating and electrochemical plating.

3. The method according to claim 1, wherein
the plating process comprises only electroless plating.

4. The method according to claim 3, wherein
before placing the electrical device on the bottom unit a protrusion is formed onto the bottom unit for supporting the electrical device.

5. The method according to claim 1, wherein
the plating process comprises a first process of electroless plating and a subsequent second process of electrochemical plating.

6. The method according to claim 1, wherein
activating selective areas is performed by a laser beam.

7. The method according to claim 1, wherein
after placing the semiconductor package on the bottom unit, the semiconductor package is pressed against the bottom unit.

8. The method according to claim 7, wherein
the semiconductor package is pressed against the bottom unit by means of a jig.

9. The method according to claim 1, wherein
the semiconductor package comprises a package body; and
by placing the semiconductor package on the bottom unit, the package body is adhered to the bottom unit.

10. The method according to claim 8, wherein
the package body is adhered to the bottom unit by means of a glue.

11. The method according to claim 1, wherein
performing the plating process comprises generating a second subset of plated regions by performing a plating process on a second subset of electrically conductive regions, wherein the second subset of plated regions comprises electrical connection lines.

12. The method according to claim 1, wherein
the at least one electrical device is a semiconductor package or a passive component.

13. An electrical module, comprising:
a bottom unit comprising a plateable encapsulant wherein selective areas are activated and turned into electrically conductive regions;
at least one electrical device comprising external contact elements and being disposed on the bottom unit with the external contact elements being electrically connected with a first subset of the electrically conductive regions by means of a first subset of plated regions.

14. The electrical module according to claim 13, further comprising
a second subset of electrically conductive regions being covered with a second subset of plated regions, wherein the second subset of plated regions comprises electrical connection lines.

15. The electrical module according to claim 13, wherein
the at least one electrical device is a semiconductor package or a passive component.

16. The method according to claim 13, wherein
the at least one electrical device comprises at least one semiconductor package and at least one passive component.

17. The method according to claim 13, wherein
the bottom unit comprises a semiconductor package.
